(19) United States
(12) Patent Application Publication
(10) Pub. No.: US 2013/0320286 A1
(43) Pub. Date: Dec. 5, 2013

(54) SWITCHING ELEMENTS AND DEVICES, MEMORY DEVICES AND METHODS OF MANUFACTURING THE SAME

(71) Applicants: Dong-soo LEE, Gunpo-si (KR); Myoung-jae LEE, Hwaseong-si (US); U-in CHUNG, Seoul (KR)

(72) Inventors: Dong-soo LEE, Gunpo-si (KR); Myoung-jae LEE, Hwaseong-si (US); U-in CHUNG, Seoul (KR)

(21) Appl. No.: 13/905,822

(22) Filed: May 30, 2013

(30) Foreign Application Priority Data
Jun. 5, 2012 (KR) 10-2012-0068177
Nov. 6, 2012 (KR) 10-2012-0125035

(51) Int. Cl. H01L 45/00

(52) U.S. Cl. CPC H01L 45/145
USPC 257/2

(57) ABSTRACT

A switching element includes: a first electrode; a second electrode; and a silicon-containing chalconitride layer between the first electrode and the second electrode. A switching device includes: a threshold switch material layer between a first electrode and a second electrode. The threshold switch material layer includes a cationic metal element, a chalcogen element, a silicon element and a nitrogen element. A memory device include: a plurality of first wirings arranged in parallel with each other; a plurality of second wirings crossing the first wirings, and arranged in parallel with each other; and a memory cell formed at each intersection of the plurality of first wirings and the plurality of second wirings. The memory cell includes a laminate having a silicon-containing chalconitride layer, an intermediate electrode, and a memory layer.

### CROSS-REFERENCE TO RELATED APPLICATIONS

This application claims priority under 35 U.S.C. §119 to Korean Patent Application No. 10-2012-0068177, filed on Jun. 25, 2012, and Korean Patent Application No. 10-2012-0125035, filed on Nov. 6, 2012, in the Korean Intellectual Property Office, the disclosures of which are incorporated herein in their entirety by reference.

### BACKGROUND

1. Field

Example embodiments relate to switching elements and devices, memory devices, and methods of manufacturing the same.

2. Description of the Related Art

Although a conventional switching device using a chalcogen compound of related art has excellent electrical properties, the switching device has a relatively low operating temperature of 400° C. or less. For instance, it is known that As₂S₃ has an operating temperature of about 150° C., As₂Se₃ has an operating temperature of about 200° C., As₂Te₃ has an operating temperature of about 250° C., As—Te—Ge has an operating temperature of about 300° C., and As—Ge—Se has an operating temperature of about 400° C. Therefore, it is not appropriate to use a switching device based on a chalcogen compound in an application field in which a succeeding process of about 400° C. or more is required, particularly in a resistance memory manufacturing field in which a deposition process of about 450° C. or more is required. Further, for instance, performance of a switching device using a telluride-based chalcogen compound such as AsTeGeSi deteriorates over time mainly because the concentration of tellurium (Te) varies in an active region of the switching device.

### SUMMARY

Example embodiments provide switching elements and devices showing improved electrical properties and/or switching properties at relatively high temperatures such as about 400° C. or higher or about 450° C. or higher, memory devices, and methods of manufacturing the same.

Additional aspects will be set forth in part in the description which follows and, in part, will be apparent from the description, or may be learned by practice of example embodiments.

At least one example embodiment provides a switching element. According to at least this example embodiment, the switching element includes: a first electrode; a second electrode; and a silicon-containing chalconitride layer between the first electrode and the second electrode.

According to at least some example embodiments, the silicon-containing chalconitride layer may have a nitride thin film formed on the surface thereof. The nitride thin film may include SiNₓ. The silicon-containing chalconitride layer may include: a chalcogenide skeleton; and a silicon nitride skeleton bonded to the chalcogenide skeleton. The chalcogenide skeleton may include a cationic metal atom bonded to a chalcogen atom. The silicon nitride skeleton may include a silicon atom bonded to a nitrogen atom. The silicon atom may be bonded to the chalcogenide atom to bond the chalcogenide skeleton to the silicon nitride skeleton. The silicon nitride skeleton may support the chalcogenide skeleton.

The silicon-containing chalconitride layer may have a composition represented by the formula MₓA₁₀₀Si_{y}N_{z}, where M is at least one of silver (Ag), arsenic (As), bismuth (Bi), germanium (Ge), indium (In), phosphorous (P), antimony (Sb) and tin (Sn). The element A may be at least one of tellurium (Te), selenium (Se), sulfur (S) and polonium (Po).

At least one other example embodiment provides a memory device. According to at least this example embodiment, the memory device includes: a plurality of first wirings arranged in parallel with each other; a plurality of second wirings crossing the first wirings, and arranged in parallel with each other; and a memory cell formed at each intersection of the first wirings and the second wirings, the memory cell including a laminate having a silicon-containing chalconitride layer, an intermediate electrode, and a memory layer.

At least one other example embodiment provides switching device. According to at least this example embodiment, the switching device includes a threshold switch material layer between a first electrode and a second electrode. The threshold switch material layer includes: a cationic metal element, a chalcogen element, a silicon element, and a nitrogen element.

At least one other example embodiment provides a memory device. According to at least this example embodiment, the memory device includes: a plurality of first wirings arranged in parallel with each other; a plurality of second wirings crossing the first wirings, and arranged in parallel with each other; and a memory cell formed at each intersection of the plurality of first wirings and the plurality of second wirings, the memory cell including a switching device, a memory layer and an intermediate electrode arranged between the switching device and the memory layer. The switching device includes a threshold switch material layer between a first electrode and a second electrode. The threshold switch material layer includes: a cationic metal element, a chalcogen element, a silicon element, and a nitrogen element.

According to at least some example embodiments, the threshold switch material layer may have a composition represented by the formula MₓA₁₀₀Si_{y}N_{z}, where M is at least one of silver (Ag), arsenic (As), bismuth (Bi), germanium (Ge), indium (In), phosphorous (P), antimony (Sb) and tin (Sn), and wherein A is at least one of tellurium (Te), selenium (Se), sulfur (S) and polonium (Po).

The cationic metal element may be bonded to the chalcogen element to form a chalcogenide skeleton. The silicon element may be bonded to the nitrogen element to form a silicon nitride skeleton. The cationic metal element may be bonded to the chalcogen element to form a chalcogenide skeleton, and the chalcogenide skeleton may be bonded to the silicon nitride skeleton.

At least one other example embodiment provides a method of manufacturing a switching element. According to at least this example embodiment, the method includes: forming a first electrode; forming a silicon-containing chalconitride layer on the first electrode; and forming a second electrode on the silicon-containing chalconitride layer.

According to at least some example embodiments, the method may further include: applying nitrogen plasma to the silicon-containing chalconitride layer before forming the second electrode.

According to at least some example embodiments, silicon-containing chalconitrides are used as a threshold switch material, and exhibit improved (e.g., excellent) electrical properties even at relatively high temperatures of about 400° C. or higher or about 450° C. or higher. In at least one example, the silicon-containing chalconitrides include a cationic metal element, a chalcogen element, a silicon element, and a nitrogen element. A cationic metal atom and a chalcogen atom are bonded to each other to form a chalcogenide skeleton. A silicon atom is bonded to the chalcogen atom of the chalcogenide skeleton. Further, the silicon atom bonded to the chalcogen atom is bonded to a nitrogen atom. A silicon nitride skeleton formed by bonding of the silicon atom and nitrogen atom is relatively stable to heat. Further, bonding of the silicon atom and chalcogen atom is also relatively stable to heat. Thus, the chalcogenide skeleton may be supported by the silicon nitride skeleton in such a way that the chalcogenide skeleton is also relatively stable to heat. Even in such a bonding structure, the chalcogenide skeleton supported by the silicon nitride skeleton exhibits improved (e.g., very superior) electrical properties in the threshold switch material. Accordingly, the silicon-containing chalconitrides may exhibit improved (e.g., very superior) threshold switching performance, even at relatively high temperatures and for a relatively long time. In comparison, a bond between chalcogen atoms and a bond between cationic metal atom and chalcogen atom in relatively simple chalcogenide compounds that do not contain the silicon nitride skeleton are relatively weak to heat. Therefore, the relatively simple chalcogenide compounds that do not contain the silicon nitride skeleton may not maintain the chalcogenide skeleton at relatively high temperatures, and emit a chalcogen element accordingly. As a result, the relatively simple chalcogenide compounds that do not contain the silicon nitride skeleton lose a threshold switching function relatively easily at relatively high temperatures, and may not recover the function even after the relatively simple chalcogenide compounds are again cooled. On the contrary, emission of a chalcogen element is suppressed (e.g., extremely or substantially suppressed) even at relatively high temperatures since the chalcogenide skeleton is heat-stably supported by the silicon nitride skeleton in the silicon-containing chalconitrides used in example embodiments.

### BRIEF DESCRIPTION OF THE DRAWINGS

These and/or other aspects will become apparent and more readily appreciated from the following description of example embodiments, taken in conjunction with the accompanying drawings in which:

FIG. 1 is a perspective view schematically illustrating an example embodiment of a memory device;

FIG. 2 is a drawing illustrating a process of manufacturing a memory device according to an example embodiment;

FIG. 3 is a photograph from the scanning electron microscope illustrating a switching element according to an example embodiment;

FIG. 4 shows graphs illustrating example switching properties at room temperature (e.g., about 25° C.), about 400° C. and about 500° C. for a switching element according to an example embodiment;

FIG. 5 shows graphs illustrating example switching properties at room temperature (e.g., about 25° C.), about 400° C. and about 500° C. for a switching element according to a Comparative Example;

FIG. 6 is a graph illustrating example switching properties at room temperature (e.g., about 25° C.) for a silicon-containing chalconitride switching element according to an example embodiment deteriorated at relatively high temperature;

FIG. 7 is a graph illustrating example switching properties at room temperature (e.g., about 25° C.) for a chalcogenide switching element according to the Comparative Example deteriorated at relatively high temperature;

FIG. 8 shows example X-ray photoelectron spectroscopy (XPS) analysis results for a silicon-containing chalconitride layer according to an example embodiment;

FIG. 9 shows example X-ray Diffraction (XRD) analysis results at various temperatures for a silicon-containing chalconitride layer according to an example embodiment before performing nitrogen plasma treatment;

FIG. 10 shows example photographs from the scanning electron microscope illustrating a switch cell in the crossbar memory arrangement according to an example embodiment;

FIG. 11 shows diagrams illustrating example XPS concentration profiles and electrical properties of thin films with or without nitrogen (N2) plasma treatment;

FIG. 12 illustrates example I-V properties for cells with the size of 30×30 (μm)² manufactured under different process conditions;

FIG. 13 illustrates total trap density and trap distance according to the sample conditions obtained from FIG. 12;

FIG. 14 illustrates example XPS analysis results for annealed thin films with or without nitrogen (N2) plasma treatment;

FIG. 15A illustrates secondary ion mass spectrometry (SIMS) analysis results for AsGeTeSiN thin films sputtered at various nitrogen partial pressure conditions;

FIG. 15B illustrates secondary ion mass spectrometry (SIMS) profile variations for about 0% and about 2% thin films after nitrogen plasma treatment;

FIG. 16 illustrates example cycling durability test results for AsGeTeSiN switches according to example embodiments;

FIG. 17 illustrates example scaling behaviors of AsGeTeSiN switches according to example embodiments;

FIG. 18 illustrates activation energy values analyzed by the measurement of temperature dependent electrical conductivity values; and

FIG. 19 illustrates a resistive random access memory (RRAM) cell having an AsGeTeSiN switch according to an example embodiment.

### DETAILED DESCRIPTION

Example embodiments will now be described more fully with reference to the accompanying drawings, in which some example embodiments are shown. In the drawings, the thicknesses of layers and regions are exaggerated for clarity. Like reference numerals in the drawings denote like elements.

Detailed illustrative embodiments are disclosed herein. However, specific structural and functional details disclosed herein are merely representative for purposes of describing example embodiments. Example embodiments may be embodied in many alternate forms and should not be construed as limited to only those set forth herein.

It should be understood, that there is no intent to limit this disclosure to the particular example embodiments disclosed. On the contrary, example embodiments are to cover all modifications, equivalents, and alternatives falling within the scope of the invention.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of this disclosure. As used herein, the term “and/or,” includes any and all combinations of one or more of the associated listed items.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting. As used herein, the singular forms “a,” “an,” and “the,” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Reference will now be made in detail to embodiments, examples of which are illustrated in the accompanying drawings, wherein like reference numerals refer to the like elements throughout. In this regard, the present embodiments may have different forms and should not be construed as being limited to the descriptions set forth herein. Accordingly, the embodiments are merely described below, by referring to the figures, to explain aspects of the present description.

At least one example embodiment provides a switching element including: a first electrode; a second electrode; and a silicon-containing chalconitride layer interposed between the first electrode and the second electrode.

At least one other example embodiment provides a switching device including: a first electrode; a second electrode; and a threshold switch material layer between the first electrode and the second electrode, the threshold switch material including a cationic metal element, a chalcogen element, a silicon element and a nitrogen element.

The first electrode may be formed of one or more of W, Ni, Al, Ti, Ta, TiN, TiW, TaN, IZO, ITO, Ir, Ru, Pd, Au, Pt, IrO₂, and the like. The second electrode may be formed of one or more of W, Ni, Al, Ti, Ta, TiN, TiW, TaN, IZO, ITO, Ir, Ru, Pd, Au, Pt and IrO₂, and the like.

The silicon-containing chalconitride layer is between the first electrode and the second electrode and includes silicon-containing chalconitrides. The silicon-containing chalconitrides are used as a threshold switch material. The silicon-containing chalconitrides contain a cationic metal element, a chalcogen element, a silicon element, and a nitrogen element.

In at least one example embodiment, a cationic metal atom and a chalcogen atom are bonded to each other to form a chalcogenide skeleton. A silicon atom is bonded to the chalcogen atom of the chalcogenide skeleton. Further, the silicon atom bonded to the chalcogen atom is also bonded to a nitrogen atom. A silicon nitride skeleton formed by bonding of the silicon atom and the nitrogen atom is relatively stable to heat. A bond between the silicon atom and the chalcogen atom is also relatively stable to heat. Thus, the chalcogenide skeleton is heat-stably supported by the silicon nitride skeleton in the silicon-containing chalconitrides. In such a bonding structure, the chalcogenide skeleton supported by the silicon nitride skeleton exhibits improved electrical properties required in the threshold switch material. Accordingly, the silicon-containing chalconitrides may exhibit improved threshold switching performance, even at relatively high temperatures, for a relatively long time.

Moreover, in example embodiments, emission of chalcogen element may be suppressed substantially even at relatively high temperatures since the chalcogenide skeleton is heat-stably supported by the silicon nitride skeleton in the silicon-containing chalconitrides.

According to at least one example embodiment, the silicon-containing chalconitrides may have a composition represented by Formula 1 shown below:

MₓA₁₀₀Si_{y}N_{z}, <Formula 1>

In Formula 1, M may be at least one element selected from the group including silver (Ag), arsenic (As), bismuth (Bi), germanium (Ge), indium (In), phosphorous (P), antimony (Sb), tin (Sn), and the like, and A may be at least one element selected from the group including tellurium (Te), selenium (Se), sulfur (S), polonium (Po), and the like.

Resistance of the silicon-containing chalconitride layer varies when a threshold voltage is applied between the first electrode and the second electrode.

A switching element according to at least some example embodiments may be manufactured by forming the second electrode on a substrate, forming the silicon-containing chalconitride layer on the second electrode, and forming the first electrode on the silicon-containing chalconitride layer. The first electrode and second electrode may be formed by methods such as a sputtering method, a chemical vapor deposition method, a plasma vapor deposition method, an atomic layer deposition method, etc. In at least one example embodiment, the substrate may be a memory layer including memory cells. In other example embodiments, the switching element may be manufactured by forming the first electrode on the silicon-containing chalconitride layer after forming the silicon-containing chalconitride layer on the second electrode.

According to at least one example embodiment, the silicon-containing chalconitride layer may be formed by sputtering a target including silicon-containing chalcogenides toward the second electrode in the presence of nitrogen. The silicon-containing chalcogenides may contain/include a cationic metal element, a chalcogen element, and a silicon element. An example of the silicon-containing chalcogenides may have a composition represented by Formula 2 shown below.

MₓA₁₀₀Si_{y}N_{z}, <Formula 1>

In Formula 2, M may be at least one element selected from the group including silver (Ag), arsenic (As), bismuth (Bi), germanium (Ge), indium (In), phosphorous (P), antimony (Sb), tin (Sn), and the like, and A may be at least one element selected from the group including of tellurium (Te), selenium (Se), sulfur (S), polonium (Po), and the like.

Sputtering of the target including silicon-containing chalcogenides is performed in the nitrogen atmosphere.

In another example embodiment, a nitride thin film may be formed on the surface of the silicon-containing chalconitride layer, for example, the contact face with the first electrode. For instance, the nitride thin film on the surface of the silicon-containing chalconitride layer may be formed by additionally applying nitrogen plasma to the silicon-containing chalconitride layer formed on the second electrode. By applying nitrogen plasma to the silicon-containing chalconitride layer, nitride thin films such as SiNₓ, GeNₓ and AlNₓ may be formed on the surface of the silicon-containing chalconitride layer according to the composition of the silicon-containing chalconitride layer. Such nitride thin films may further suppress diffusion of chalcogen elements such as selenium (Se) or tellurium (Te) from the silicon-containing chalconitride layer. Accordingly, deterioration of the silicon-containing chalconitride layer over time may be further suppressed.

According to at least one example embodiment, a switching element may be used in any memory cell including a memory layer and a switching element. Examples of the memory cell to which the switching element may be applied may include a volatile memory cell and/or a non-volatile memory cell. An example of a volatile memory device to which the switching element may be applied may include a Dynamic Random Access Memory (DRAM). Examples of a non-volatile memory device to which the switching element may be applied may include a Magnetic Random Access Memory (MRAM), a Ferroelectric Random Access Memory (FRAM), a Phase-change Random Access Memory (PRAM), a Resistance Random Access Memory (RRAM), etc.

According to at least one other example embodiment, a memory device includes: a plurality of first wirings arranged in parallel with each other; a plurality of second wirings crossing the first wirings, and arranged in parallel with each other; and memory cells, each of which is arranged at an intersection of the first and second wirings. The memory cell is a laminate including a silicon-containing chalconitride layer, an intermediate electrode, and a memory layer.

According to at least one other example embodiment, a nitride thin film may be formed on the surface of the silicon-containing chalconitride layer. The nitride thin film may include SiNₓ.

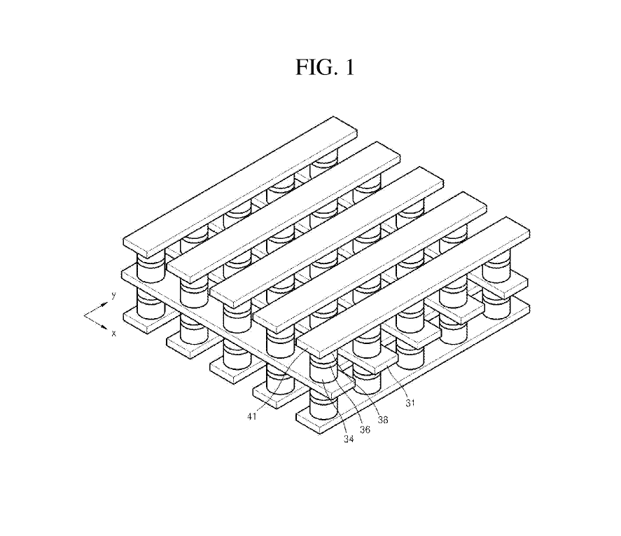

FIG. 1 is a perspective view schematically illustrating an example embodiment of a memory device.

Referring to FIG. 1, a plurality of first wirings 41 are arranged in parallel with each other. A plurality of second wirings 31 are arranged in parallel with each other. The first wirings 41 and the second wirings 31 are arranged on different planes in such a way that the first and second wirings 41 and 31 cross each other. The memory cell is arranged at each intersection (e.g., each of the intersecting points) of the first wirings 41 and the second wirings 31. The memory cell is formed in the form of a laminate including a silicon-containing chalconitride layer 38, an intermediate electrode 36, and a memory layer 34.

The first wirings 41 may be formed of, for example, one or more of W, Ni, Al, Ti, Ta, TiN, TiW, TaN, IZO, ITO, Ir, Ru, Pd, Au, Pt, IrO₂, and the like. The second wirings 31 may be formed of one or more of W, Ni, Al, Ti, Ta, TiN, TiW, TaN, IZO, ITO, Ir, Ru, Pd, Au, Pt, IrO₂, and the like. The intermediate electrode 36 may be formed of one or more of W, Ni, Al, Ti, Ta, TiN, TiW, TaN, IZO, ITO, Ir, Ru, Pd, Au, Pt, IrO₂, and the like.

Examples of the memory layer 34 may include a volatile memory layer and a non-volatile memory layer.

An example of the volatile memory layer may include a dielectric layer for Dynamic Random Access Memory (DRAM). Examples of the non-volatile memory layer may include a memory layer for a Magnetic Random Access Memory (MRAM), a memory layer for a Ferroelectric Random Access Memory (FRAM), a memory layer for a Phase-change Random Access Memory (PRAM), a memory layer for RRAM (Resistance Random Access Memory), etc.

More specifically, examples of the memory layer for a Resistance Random Access Memory (RRAM) may include one or more materials selected from the group including NiO, TiO₂, Al₂O₃, HfO, ZrO, ZnO, WO₃, CoO, Nb₂O₅, TaO, Ta₂O₅, and the like. In at least one other example embodiment, examples of the memory layer for a Resistance Random Access Memory (RRAM) may additionally include metal ions selected from the group including Ni ions, Ti ions, Hf ions, Zr ions, Zn ions, W ions, Co ions, Nb ions, and the like.

Still referring to FIG. 1, the first wirings 41, the silicon-containing chalconitride layer 38, and the intermediate electrode 36 function as a switching element. When a threshold voltage is applied between the first wirings 41 and the intermediate electrode 36, the resistance of the silicon-containing chalconitride layer 38 varies.

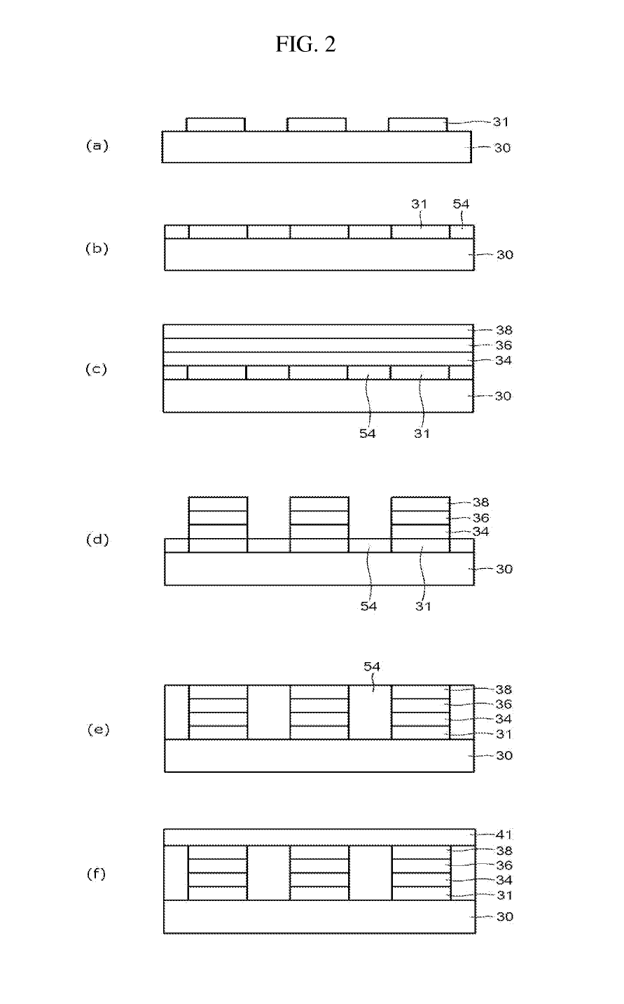

FIG. 2 is a drawing illustrating a method of manufacturing a memory device according to an example embodiment.

Referring to steps A and B of FIG. 2, empty spaces between the second wirings 31 are filled with an insulating layer 54 (e.g., SiO₂) after forming a pattern of second wirings 31 in the x direction (e.g., into the drawing) on a substrate 30.

Referring to steps C to E of FIG. 2, a plurality of memory cells are formed by sequentially laminating and patterning the memory layer 34, intermediate electrode 36, and silicon-containing chalconitride layer 38 on the pattern of second wirings 31 filled with the insulating layer 54. Accordingly, each of the memory cells includes a silicon-containing chalconitride layer 38, an intermediate electrode 36, and a memory layer 34. Spaces between the memory cells are filled with the insulating layer 54 such as SiO₂ to flatten the memory cell pattern.

Referring to step F of FIG. 2, a pattern of first wirings 41 in the y direction (e.g., left to right in the drawings) is formed on the flattened memory cell pattern. Accordingly, the first wirings 41 and the second wirings 31 intersect. Although a layer of a memory cell array is formed in an example embodiment of FIG. 2, two or more layers of memory cell array may be formed by repeating steps A to F of FIG. 2.

At least one other example embodiment of a method of manufacturing a switching element includes: forming a first electrode; forming a silicon-containing chalconitride layer on the first electrode; and forming a second electrode on the silicon-containing chalconitride layer. At least one other example embodiment of a method of manufacturing a switching element may additionally include applying nitrogen plasma to the silicon-containing chalconitride layer before forming the second electrode.

### EXAMPLES

### Example 1

### Manufacturing of a Silicon-Containing Chalconitride Switching Element with the Size of about 500 Nm×500 Nm

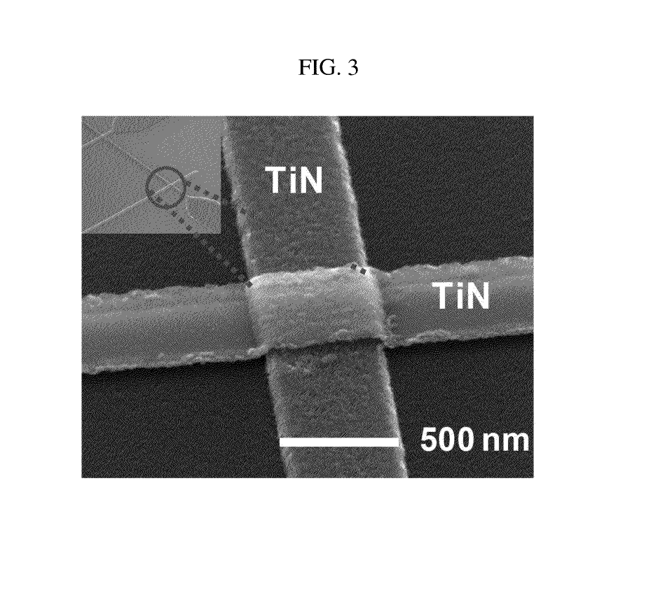

In one example, a silicon-containing chalconitride switching element was manufactured by forming a TiN upper electrode wiring on the silicon-containing chalconitride layer after forming a silicon-containing chalconitride layer on a TiN lower electrode wiring using photolithography method. The TiN lower electrode wiring and the TiN upper electrode wiring were arranged in such a direction that the TiN lower electrode wiring and the TiN upper electrode wiring crossed at a right angle. The TiN lower electrode wiring and the TiN upper electrode wiring had a line width of about 500 nm. A silicon-containing chalconitride layer having a size of about 500 nm×500 nm was formed between the TiN lower electrode wiring and the TiN upper electrode wiring at the intersecting point of the TiN lower electrode wiring and the TiN upper electrode wiring. A photograph from a scanning electron microscope illustrating such a manufactured switching element of the Example 1 is illustrated in FIG. 3. Example switching properties at room temperature (e.g., about 25° C.), about 400° C. and about 500° C. of the switching element of the Example 1 are shown in FIG. 4.

### Comparative Example 1

### Manufacturing of a Chalcogenide Switching Element with the Size of about 500 Nm×500 Nm

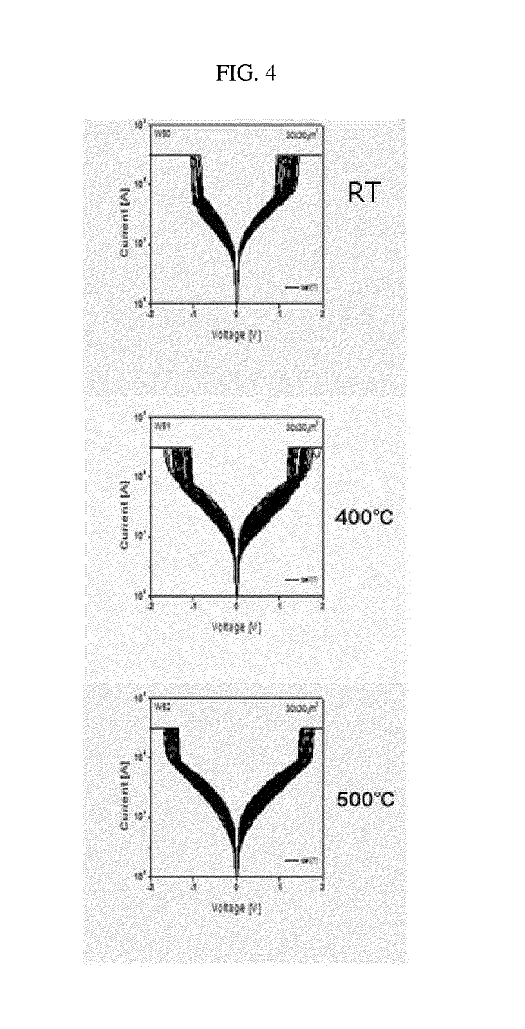

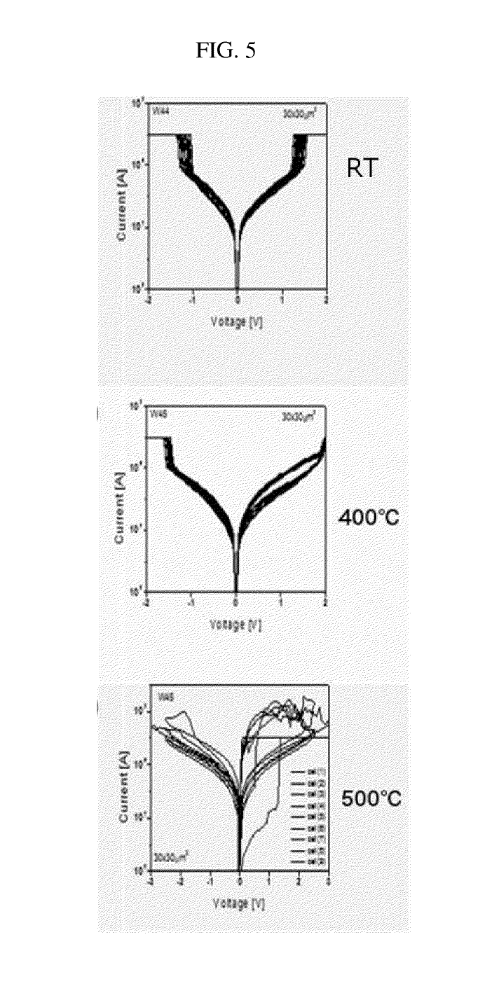

In this Comparative Example, a chalcogenide switching element was manufactured by forming a TiN upper electrode wiring on the chalcogenide layer after forming a chalcogenide layer on a TiN lower electrode wiring using photolithography. The TiN lower electrode wiring and the TiN upper electrode wiring were arranged in such a direction that the TiN lower electrode wiring and the TiN upper electrode wiring crossed at right angles. The TiN lower electrode wiring and the TiN upper electrode wiring had a line width of about 500 nm. A chalcogenide layer having a size of about 500 nm×500 nm was formed between the TiN lower electrode wiring and the TiN upper electrode wiring at the intersecting point of the TiN lower electrode wiring and the TiN upper electrode wiring. Example switching properties at room temperature (e.g., about 25° C.), about 400° C. and about 500° C. of a manufactured switching element of the Comparative Example 1 are shown in FIG. 5.

Evaluation Results 1 of Switching Properties

As illustrated in FIG. 5, example switching properties of a chalcogenide switching element of the related art fall (e.g., remarkably drop) at a temperature of about 400° C. or higher. On the contrary, as illustrated in FIG. 4, the silicon-containing chalconitride switching element of the Example 1 exhibits more stable switching properties even at relatively high temperature processes of about 500° C.

### Example 2

### Manufacturing of a Silicon-Containing Chalconitride Switching Element by N₂ Plasma Treatment

In this example, a silicon-containing chalconitride switching element was manufactured by forming a TiN upper electrode wiring on the silicon-containing chalconitride layer having the nitride thin film after forming a silicon-containing chalconitride layer having a nitride thin film on a TiN lower electrode wiring using photolithography method. The TiN lower electrode wiring and the TiN upper electrode wiring were arranged in such a direction that the TiN lower electrode wiring and the TiN upper electrode wiring crossed at a right angle. The TiN lower electrode wiring and the TiN upper electrode wiring had a line width of about 500 nm. A silicon-containing chalconitride layer having a size of about 500 nm×500 nm was formed between the TiN lower electrode wiring and the TiN upper electrode wiring at the intersecting point of the TiN lower electrode wiring and the TiN upper electrode wiring. Further, a sputtered silicon-containing chalconitride layer was treated by nitrogen plasma before forming the upper electrode.

Evaluation Results of Switching Properties after Suffering Relatively High Temperature Deterioration

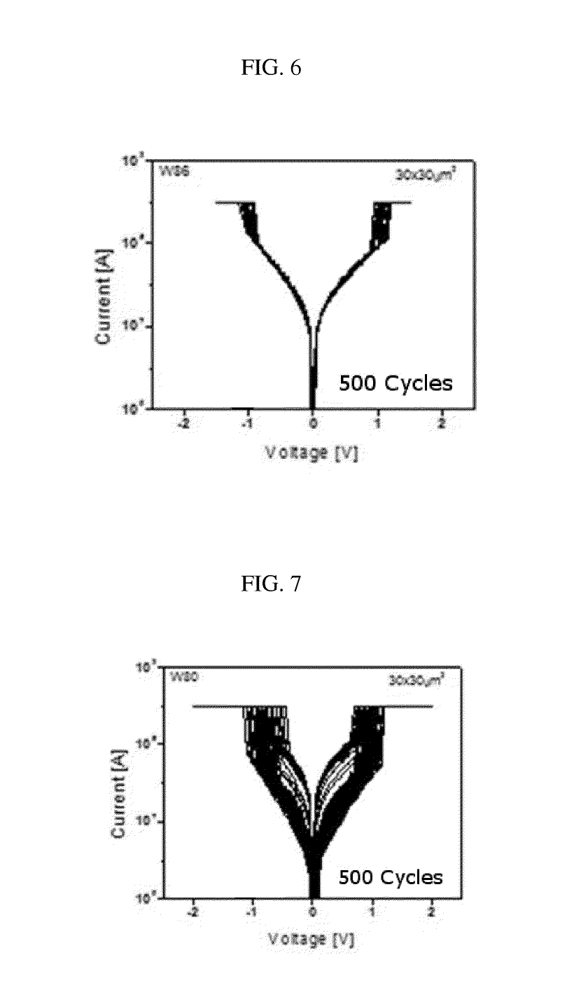

A silicon-containing chalconitride switching element of Example 2 and a chalcogenide switching element of the Comparative Example 1 were high temperature deteriorated at a relatively high temperature of about 450° C. Switching properties at room temperature (e.g., about 25° C.) for the silicon-containing chalconitride switching element of Example 2 deteriorated at relatively high temperature are shown in FIG. 6. Switching properties at room temperature (e.g., about 25° C.) for the chalcogenide switching element of the Comparative Example 1 deteriorated at relatively high temperature are shown in FIG. 7.

As shown, the silicon-containing chalconitride switching element of Example 2 exhibits more stable switching properties even after high temperature deterioration as illustrated in FIG. 6.

### Example 3

### Formation of a Silicon-Containing Chalconitride Layer

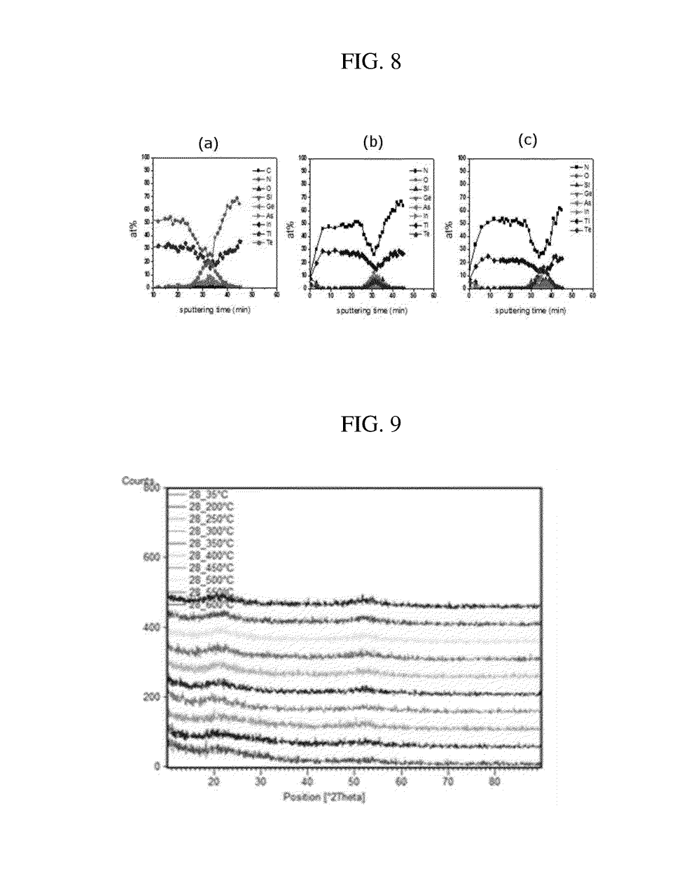

In this example, a silicon-containing chalconitride layer was formed on a substrate, and the silicon-containing chalconitride layer was treated by nitrogen plasma. Example x-ray photoelectron spectroscopy (XPS) analysis results for the silicon-containing chalconitride layer are shown in FIG. 8.

More specifically, FIG. 8A shows example analysis results for the silicon-containing chalconitride layer before performing nitrogen plasma treatment, FIG. 8B shows example analysis results obtained by high temperature deteriorating the silicon-containing chalconitride layer before performing nitrogen plasma treatment at about 450° C., and FIG. 8C shows example analysis results obtained by high temperature deteriorating the silicon-containing chalconitride layer after performing nitrogen plasma treatment at about 450° C.

In case of chalcogenides, out-diffusion of tellurium (Te) is generated (e.g., severely generated) after deterioration at a high temperature of about 450° C. However, as illustrated in FIG. 8C, out-diffusion of tellurium (Te) was suppressed (e.g., substantially suppressed) even after high temperature deterioration in case of nitrogen plasma treated silicon-containing chalconitrides.

FIG. 9 shows example X-ray Diffraction (XRD) analysis results at various temperatures for a silicon-containing chalconitride layer before performing nitrogen plasma treatment.

As illustrated in FIG. 9, the silicon-containing chalconitrides maintain an amorphous state even after performing heat treatment at high temperatures of about 600° C. or higher as well as at room temperature.

### Example 4

### Evaluation of Switching Properties

In order to reach a higher density such as about 1 Tbit, a 3-dimensional cell laminating technology, a miniaturization technology, a multi-level cell (MLC) technology, and a technology of miniaturization up to a node of about less than about 10 nm may be utilized simultaneously and/or concurrently. In a typical memory system, a memory device (or cell) has a selector (or switch device) and a storage element. A Si-based transistor or a 2-terminal Si diode has generally been used as a switch element. This is due to restrictions such as sufficient current density and reliability. However, some materials such as Mixed Ionic Electronic Conduction (MIEC), bidirectional varistors, and oxide diodes have recently been suggested as a Si substitute for a 2-terminal selecting device. On the other hand, chalcogenide glass has been studied as a storage element since chalcogenides have relatively stable amorphous and crystalline phases, and have a history that the chalcogenides have been used in the optical storage field for a relatively long time. However, if electronic charge injection is used in AsTeGeSi-based material, a threshold switching phenomenon may also be observed.

FIG. 10A illustrates a path of stray current required by a switch in a crossbar type memory.

FIG. 10B shows a photograph from a scanning electron microscope illustrating an example 500 nm switch cell having TiN upper and lower electrodes.

FIG. 10C shows a photograph from a scanning electron microscope illustrating an example 30 nm switch cell in which electron beam lithography was used. In this example, the cell has Ti upper and lower electrodes.

FIG. 10D illustrates switching properties of an example 500 nm AsTeGeSiN cell, where the inserted photograph shows crossbar array of a switch device.

### Example 5

### N₂ Plasma Nitridation Hardening

In connection with this example, deterioration properties for an AsTeGeSiN switch were analyzed after applying annealing for simulating deterioration.

FIG. 11A illustrates an annealed sample, and FIG. 11B illustrates example variation of switch properties for a sample that passed through N₂ plasma treatment and annealing.

As illustrated in FIG. 11B, distribution in threshold voltage and current is decreased (e.g., greatly decreased) in case of the N₂ plasma treated sample.

FIG. 11C is an X-ray photoelectron spectroscopy (XPS) concentration file of a thin film, which shows a relatively low tellurium (Te) concentration since the thin film has not been treated with N₂, and FIG. 11D is an X-ray photoelectron spectroscopy (XPS) concentration file of a thin film, which shows a relatively high tellurium (Te) concentration since the thin film has been treated with N₂. As shown, the actual tellurium (Te) concentration has decreased in case of a sample that has not been treated with N₂ plasma.

An example threshold voltage and current distribution are represented in FIGS. 11E and 11F, respectively, with respect to the case to which cycle repetition has been applied. Modeling for off state conduction was based on a trap-limited conduction (TLC) model.

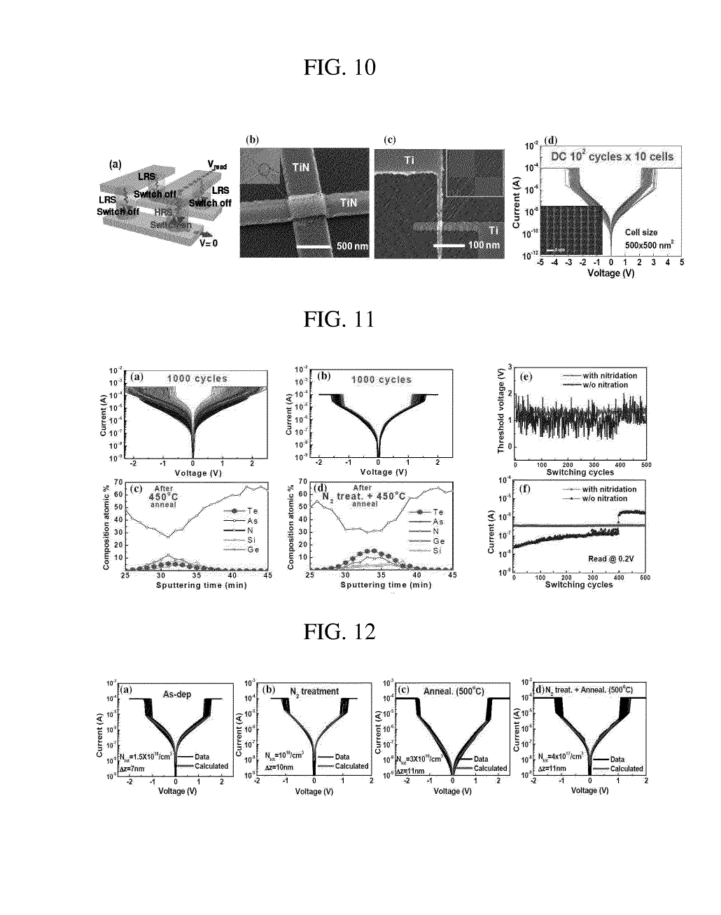

FIG. 12 illustrates example I-V properties for cells with a size of about 30×30 (μm)² manufactured at different process conditions. Respective samples were measured for 500 cycles. Total trap density Nₜₒₜ and a distance between traps Δ_{z} were sampled using the trap-limited conduction (TLC) model.

FIG. 12A is a sample as it is in the deposited state, FIG. 12B is a N₂ treated sample, FIG. 12C is a vacuum annealed sample, and FIG. 12D is a sample that was treated with N₂ and then annealed.

Since the tellurium (Te) concentration is directly related with the trap density, it may be seen from the figures that barrier to the loss of tellurium (Te) may be provided by N₂ plasma treatment.

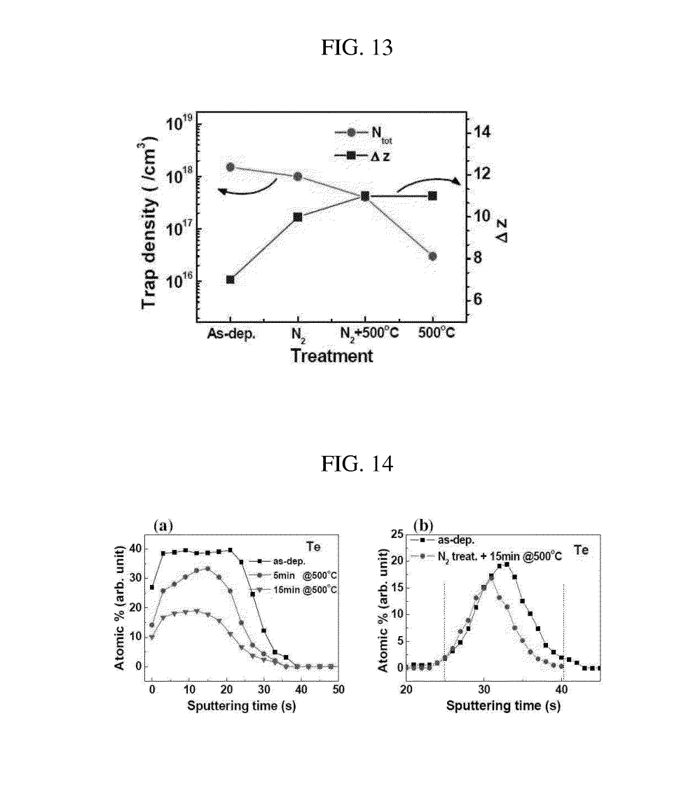

FIG. 13 illustrates example total trap density and trap distance according to the sample conditions obtained from FIG. 12.

FIG. 14A illustrates example X-ray photoelectron spectroscopy (XPS) analysis results for a thin film, which has been annealed without being treated with nitrogen (N₂) plasma, and FIG. 14B illustrates example X-ray photoelectron spectroscopy (XPS) analysis results for a thin film, which has been annealed after the thin film has been treated with nitrogen (N₂) plasma.

It may be seen from FIG. 14A that the concentration of element tellurium (Te) has been reduced (e.g., seriously or substantially reduced) according to an increase in the annealing time after performing annealing. For the purpose of comparison, the result of the sample that has been nitrided with N₂ plasma is represented in FIG. 14B. Reduction of the tellurium (Te) concentration was suppressed, and a high tellurium (Te) concentration was maintained even after the post-annealing.

As a result of more close examination, it turned out that a SiN thin film was formed on the surface of a sample through nitrogen plasma treatment. The formation of SiN during the deposition process of an AsTeGeSiN thin film was compared using secondary ion mass spectrometry (SIMS) analysis.

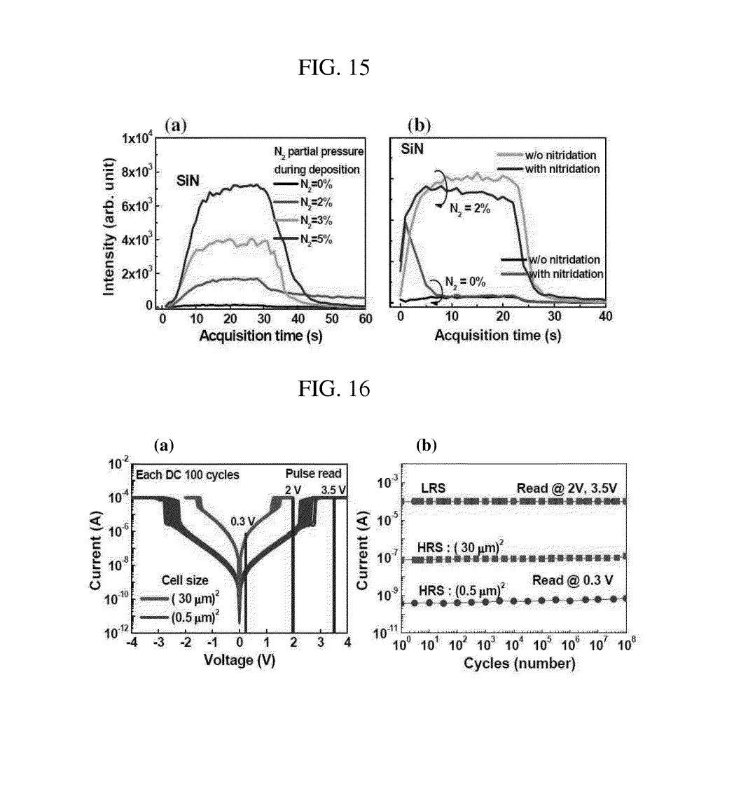

FIG. 15A illustrates an example secondary ion mass spectrometry (SIMS) profile for thin films deposited at about 0%, about 2%, about 3% and about 5% nitrogen (N₂) partial pressures during reactive sputtering. Comparisons between thin films deposited at about 0% and about 2% nitrogen partial pressures before nitrogen plasma treatment and the thin films after nitrogen plasma treatment are illustrated in FIG. 15B.

As shown, the SiN thin film was formed on the surface of the sample. The SiN thin film was formed on the surface of the sample in case of the thin film deposited at about 0% nitrogen partial pressure, and a signal strength of the SiN thin film was increased in case of the thin film deposited at about 2% nitrogen partial pressure.

### Example 6

### Device Performance

FIG. 16 illustrates example cycling durability values for AsGeTeSiN switches.

FIG. 16A illustrates example direct current I-V data during 100 cycles for cells with the size of about 30×30 (μm)² and cells with the size of about 500×500 (μm)², and FIG. 16B illustrates example pulse cycling measurement results showing 10⁸ cycling durability for cells with the size of about 30×30 (μm)² and cells with the size of about 500×500 (μm)².

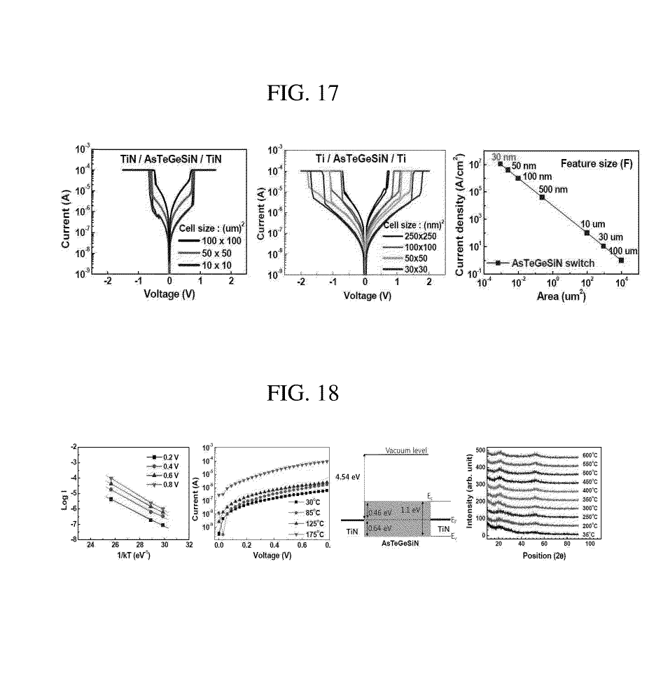

FIG. 17 illustrates example scaling behaviors of AsGeTeSiN switches.

FIG. 17A illustrates example threshold switching of a device with the size of about 100×100 (μm)² to about 10×10 (μm)², and FIG. 17B illustrates example threshold switching of a device with the size of about 250×250 (μm)² to about 30×30 (μm)². FIG. 17C illustrates that current densities of the cells increase more as size of the cells according to example embodiments decrease. This corresponds to what is expected for filamentary switching mechanism. In case of cells with the size of about 30 nm×30 nm, the current density of about 1.1×10⁷ A/cm² is a numerical value that is comparable to a current density value of a Si diode.

FIG. 18 illustrates example activation energy values analyzed by the measurement of temperature dependent electrical conductivity values.

FIG. 18A illustrates an example measurement result of temperature dependent electrical conductivity values for sampling parameters for a trap-limited conduction (TLC) model, and FIG. 18B illustrates example activation energy values sampled from I-V of FIG. 18A, wherein an average Ea=˜0.45 eV. FIG. 18C is an example band alignment drawing illustrating a device structure according to an example embodiment, which is confirmed by measuring UPS obtained after performing the calculation in FIGS. 18A and 18B. FIG. 18D illustrates that the amorphous phase is well maintained even at temperatures over about 600° C. through the high temperature X-ray Diffraction (XRD) analysis.

### Example 7

### Integration

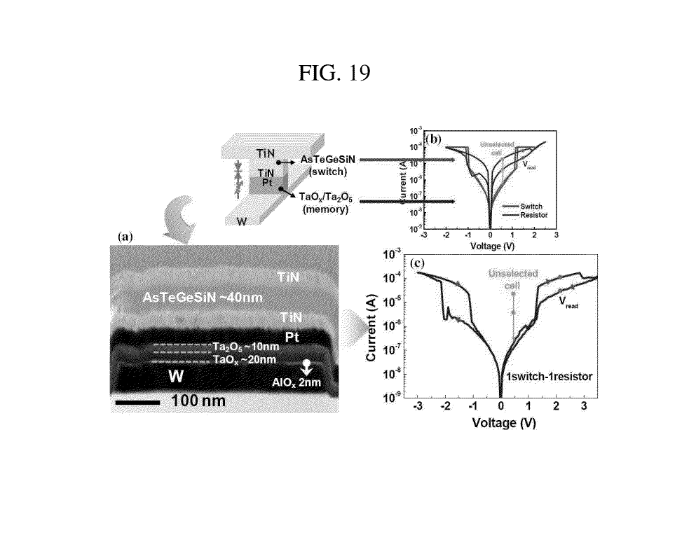

A 1-switch-1-resistor (1S-1R) memory cell was manufactured. A photograph from transmission electron microscope for an integrated about 500 nm cell according to an example embodiment is illustrated in FIG. 19A, wherein a W bottom electrode was used, and a 2 nm AlOₓ thin film was used to protect the W surface. A resistance memory stack was manufactured by performing oxidation using oxygen plasma after reactive sputtering of TaOₓ, thereby forming a Ta₂O₅ insulating layer with the thickness of about 10 nm. The intermediate electrode was a Pt/TiN double layer.

After depositing an AsGeTeSiN switch layer with the thickness of about 40 nm, a TiN upper electrode was formed. Example device performances of individual elements are illustrated in FIG. 19B.

Finally, properties of an assembled 1S-1R switch are shown in FIG. 19C. Performances of the AsTeGeSiN switch according to this example are summarized in Table 1.

TABLE 1

| Items | Values |
|---|---|
| Maximum current density | 1.1 × 10⁷ A/cm² (@ 30 nm node) |
| Selectivity (Δ I @ Iₛₑₜ, I_{read} (½Vₛₑₜ) | 10² (@ 30 μm), 10³ (@ 30 nm) |
| Durability | DC: >10³, pulse: >10⁸ cycles |
| Processing temperature | 200° C. |
| High temperature stability | <500° C. |

Deterioration problems according to time may be suppressed and/or prevented by using nitrogen plasma treatment. A device according to at least some example embodiments has scalability with a relatively wide (e.g., very wide) width, may be miniaturized up to a size of about 30 nm, and may represent a superior (e.g., very superior) switching current density even in this case. For instance, even when the manufacturing temperature was only about 200° C., devices according to one or more example embodiments may be more stably maintained in the post-processing step of about 500° C., and it turned out that the device was more suitable for forming the laminated structure accordingly.

It should be understood that the example embodiments described therein should be considered in a descriptive sense only and not for purposes of limitation. Descriptions of features or aspects within each example embodiment should typically be considered as available for other similar features or aspects in other example embodiments.

1. A switching element comprising:
a first electrode;
a second electrode; and
a silicon-containing chalconitride layer interposed between the first electrode and the second electrode.

2. The switching element of claim 1, wherein the silicon-containing chalconitride layer has a nitride thin film formed on the surface thereof.

3. The switching element of claim 2, wherein the nitride thin film comprises includes SiNx.

4. The switching element of claim 1, wherein the silicon-containing chalconitride layer comprises:
a chalcogenide skeleton; and
a silicon nitride skeleton bonded to the chalcogenide skeleton.

5. The switching element of claim 4, wherein the chalcogenide skeleton includes a cationic metal atom bonded to a chalcogen atom.

6. The switching element of claim 5, wherein the silicon nitride skeleton includes a silicon atom bonded to a nitrogen atom.

7. The switching element of claim 6, wherein the silicon atom is bonded to the chalcogenide atom to bond the chalcogenide skeleton to the silicon nitride skeleton.

8. The switching element of claim 4, wherein the silicon nitride skeleton includes a silicon atom bonded to a nitrogen atom.

9. The switching element of claim 4, wherein the silicon nitride skeleton supports the chalcogenide skeleton.

10. The switching element of claim 1, wherein the silicon-containing chalconitride layer has a composition represented by the formula MxA100SiyNz, where M is at least one of silver (Ag), silver (Ag), arsenic (As), bismuth (Bi), germanium (Ge), indium (In), phosphorous (P), antimony (Sb) and tin (Sn), and A is at least one of chalcogen elements.

11. The switching element of claim 10, wherein A is at least one of tellurium (Te), selenium (Se), sulfur (S) and polonium (Po).

12. A memory device comprising:
a plurality of first wirings arranged in parallel to with each other;
a plurality of second wirings which crossing with the first wirings, and are arranged in parallel to with each other; and
a memory cell formed in at each of intersecting points intersection of the plurality of first wirings and the plurality of second wirings, the memory cell comprising including a laminate having a silicon-containing chalconitride layer, an intermediate electrode, and a memory layer.

13. The memory device of claim 12, wherein the silicon-containing chalconitride layer has a nitride thin film formed on the surface thereof.

14. The memory device of claim 12, wherein the silicon-containing chalconitride layer comprises:
a chalcogenide skeleton; and
a silicon nitride skeleton bonded to the chalcogenide skeleton.

15. The memory device of claim 12, wherein the silicon-containing chalconitride layer has a composition represented by the formula MxA100SiyNz, where M is at least one of silver (Ag), silver (Ag), arsenic (As), bismuth (Bi), germanium (Ge), indium (In), phosphorous (P), antimony (Sb) and tin (Sn), and wherein A is at least one of tellurium (Te), selenium (Se), sulfur (S) and polonium (Po).

16.-17. (canceled)

18. A switching device comprising:
a threshold switch material layer between a first electrode and a second electrode, the threshold switch material layer including a cationic metal element, a chalcogen element, a silicon element and a nitrogen element.

19. The switching device of claim 18, wherein the threshold switch material layer has a composition represented by the formula MxA100SiyNz, where M is at least one of silver (Ag), silver (Ag), arsenic (As), bismuth (Bi), germanium (Ge), indium (In), phosphorous (P), antimony (Sb) and tin (Sn), and wherein A is at least one of tellurium (Te), selenium (Se), sulfur (S) and polonium (Po).

20. The switching device of claim 18, wherein the cationic metal element is bonded to the chalcogen element to form a chalcogenide skeleton.

21. The switching device of claim 20, wherein the silicon element is bonded to the nitrogen element to form a silicon nitride skeleton.

22. The switching device of claim 21, wherein the silicon element is bonded to the chalcogenide element to bond the chalcogenide skeleton to the silicon nitride skeleton.

23. The switching device of claim 21, wherein the silicon nitride skeleton supports the chalcogenide skeleton.

24. The switching device of claim 18, wherein the silicon element is bonded to the nitrogen element to form a silicon nitride skeleton.

25. A memory device comprising:
a plurality of first wirings arranged in parallel with each other;
a plurality of second wirings crossing the first wirings, and arranged in parallel with each other; and
a memory cell formed at each intersection of the plurality of first wirings and the plurality of second wirings, the memory cell including the switching device of claim 18, a memory layer and an intermediate electrode arranged between the switching device and the memory layer.

26. The memory device of claim 25, wherein the threshold switch material layer has a composition represented by the formula MxA100SiyNz, where M is at least one of silver (Ag), silver (Ag), arsenic (As), bismuth (Bi), germanium (Ge), indium (In), phosphorous (P), antimony (Sb) and tin (Sn), and wherein A is at least one of tellurium (Te), selenium (Se), sulfur (S) and polonium (Po).

27. The memory device of claim 25, wherein the cationic metal element is bonded to the chalcogen element to form a chalcogenide skeleton.

28. The memory device of claim 27, wherein the silicon element is bonded to the nitrogen element to form a silicon nitride skeleton.

29. The memory device of claim 28, wherein the silicon element is bonded to the chalcogenide element to bond the chalcogenide skeleton to the silicon nitride skeleton.

30. The memory device of claim 25, wherein the silicon element is bonded to the nitrogen element to form a silicon nitride skeleton.
